(19) United States
(12) Patent Application Publication
(10) Pub. No.: US 2013/0200503 A1
(43) Pub. Date: Aug. 8, 2013

(54) PROTECTIVE LAYERS IN SEMICONDUCTOR PACKAGING

(71) Applicants: Chan Boon Meng, Ipoh (MY); Law Wai Ling, Ipoh (MY)

(72) Inventors: Chan Boon Meng, Ipoh (MY); Law Wai Ling, Ipoh (MY)

(73) Assignee: CARSEM (M) SDN, BHD., Ipoh (MY)

(21) Appl. No.: 13/563,487

(22) Filed: Jul. 31, 2012

(30) Foreign Application Priority Data
Feb. 8, 2012 (MY) PI 2012000525

(51) Int. Cl. H01L 23/495; H01L 21/56

(52) U.S. Cl. 257/666; 438/118; 257/E23.031; 257/E21.502

(57) ABSTRACT

A semiconductor package includes a semiconductor die having an upper surface with bond pads thereon. A plurality of leads surround sides of the semiconductor die. Bonding wires couple each of the bond pads to a corresponding one of the plurality of leads. An encapsulant covers the upper surface and the sides of the semiconductor die and the bonding wires. The encapsulant also covers a portion of a top of each of the plurality of leads and sides of the plurality of leads that are nearest the semiconductor die. A bottom of each of the plurality of leads and the sides of the plurality of leads that are farthest from the semiconductor die are exposed outside the encapsulant. A protective film covers a lower surface of the semiconductor die and has a bottom that is substantially coextensive with the bottom of each of the plurality of leads.

### CROSS-REFERENCE TO RELATED APPLICATIONS

This application claims priority to Malaysian Patent Application No. PI 2012000525, filed Feb. 8, 2012, the disclosure of which is incorporated herein by reference in its entirety for all purposes.

### FIELD OF THE INVENTION

The present invention relates in general to semiconductor packaging and, more particularly, to semiconductor packages having a protective layer covering a lower surface of a semiconductor die.

### BACKGROUND

Semiconductor packages are continually being designed to be more compact. This can be accomplished by reducing a thickness of the semiconductor packages and/or minimizing a size of the semiconductor packages.

Various methods have been used to achieve these objectives. For example, loop height of bonding wires can impact thickness and size of semiconductor packages, and various bonding techniques have been used to reduce the loop height. Also, thickness and size of die attach paddles (used to support semiconductor die in semiconductor packages) can impact thickness and size of semiconductor packages, and various techniques have been employed to reduced the thickness and size of the die attach paddles.

Despite these methods, additional improvements are continuously sought to further reduce thickness and size of semiconductor packages.

### SUMMARY

Embodiments of the present invention enable thickness and size of semiconductor packages to be reduced. In some embodiments, for example, a protective layer may be used in a semiconductor package in place of a die attach paddle. The protective layer covers a lower surface of a semiconductor die and may be thinner than the die attach paddle it replaces. This enables a reduction in thickness of the semiconductor package. Eliminating the die attach paddle also enables a reduction in size of the semiconductor package because the semiconductor package is not constrained by design rules associated with minimum semiconductor die to die attach paddle size ratios. Details of these and other embodiments of the invention are described below.

In accordance with an embodiment of the present invention, a semiconductor package includes a semiconductor die having an upper surface, a lower surface, and sides. The upper surface of the semiconductor die has a plurality of bond pads thereon. The semiconductor package also includes a plurality of leads surrounding the sides of the semiconductor die and spaced from the sides of the semiconductor die. Each of the plurality of leads have a top, a bottom, and sides. The semiconductor package also includes plurality of bonding wires that each couple one of the plurality of bond pads on the upper surface of the semiconductor die to a corresponding one of the plurality of leads surrounding the semiconductor die. The semiconductor package also includes an encapsulant that covers the upper surface and the sides of the semiconductor die and the plurality of bonding wires. The encapsulant also covers at least a portion of the top of each of the plurality of leads and the sides of each of the plurality of leads that are nearest the semiconductor die. At least a portion of the bottom of each of the plurality of leads and at least a portion of the sides of each of the plurality of leads that are farthest from the semiconductor die are exposed outside the encapsulant. The semiconductor package also includes a protective film that covers the lower surface of the semiconductor die. A bottom of the protective film is substantially coextensive with at least a portion of the bottom of each of the plurality of leads.

In an embodiment, a plane extending along the lower surface of the semiconductor die lies between the top and the bottom of each of the plurality of leads.

In another embodiment, the bottom of the protective film is exposed along a lower surface of the semiconductor package.

In another embodiment, the encapsulant extends under at least a portion of the bottom of each of the plurality of leads.

In another embodiment, at least a portion of the bottom of each of the plurality of leads is exposed along a lower surface of the semiconductor package.

In another embodiment, at least a portion of the sides of each of the plurality of leads that are farthest from the semiconductor die are exposed along a side of the semiconductor package.

In another embodiment, the protective film comprises an epoxy.

In another embodiment, the protective film has a thickness of at least about 10 μm.

In yet another embodiment, the bottom of the protective film is exposed along a lower surface of the semiconductor package and is substantially flush with a lower surface of the semiconductor package.

In accordance with another embodiment of the present invention, a method of forming semiconductor packages includes providing a leadframe strip having a plurality of inner frames. Each inner frame may have a plurality of leads surrounding a die receiving area. The method also includes attaching an adhesive tape to a backside of the leadframe strip. The adhesive tape may be exposed in the die receiving area of each inner frame. The method also includes placing a semiconductor die having a protective film extending along a lower surface of the semiconductor die in the die receiving area of each inner frame so that (1) the plurality of leads of each inner frame surround the semiconductor die and are spaced from sides of the semiconductor die, and (2) a bottom of the protective film is substantially coextensive with a bottom of each of the plurality of leads surrounding the semiconductor die. The method also includes coupling bond pads on an upper surface of each of the semiconductor die to corresponding ones of the plurality of leads surrounding the semiconductor die in each frame. The method also includes forming an encapsulant covering the upper surface and the sides of each of the semiconductor die in each frame. The encapsulant may also cover at least a portion of a top of each of the plurality of leads and sides of the plurality of leads that are nearest the semiconductor die. At least a portion of the bottom of each of the plurality of leads and at least a portion of the sides of the plurality of leads that are farthest from the semiconductor die may be exposed outside the encapsulant. The method also includes singulating each of the inner frames from the leadframe strip to form the semiconductor packages.

In an embodiment, after each of the semiconductor die are placed in the die receiving area of each inner frame, a plane extending along the lower surface of each of the semiconductor die lies between the top and the bottom of each of the plurality of leads surrounding the semiconductor die.

In another embodiment, after each of the inner frames are singulated from the leadframe strip, the bottom of the protective film is exposed along a lower surface of each semiconductor package.

In another embodiment, after each of the semiconductor die are placed in the die receiving area of each inner frame, the protective film along the lower surface of each of the semiconductor die has a thickness of at least about 10 μm.

In yet another embodiment, after each of the inner frames are singulated from the leadframe strip, the bottom of the protective film is substantially flush with a lower surface of the semiconductor package.

In accordance with yet another embodiment of the present invention, a method of forming a semiconductor package includes providing a frame having a plurality of leads surrounding a die receiving area. The frame may have an adhesive tape extending along a backside of the frame. The method also includes placing a semiconductor die in the die receiving area so that (1) the plurality of leads surround the semiconductor die and are spaced from sides of the semiconductor die, and (2) a protective film extends between a lower surface of the semiconductor die and the adhesive tape in the die receiving area. The method also includes coupling bond pads on an upper surface of the semiconductor die to corresponding ones of the plurality of leads using bonding wires and forming an encapsulant covering the upper surface and the sides of the semiconductor die and the bonding wires. The encapsulant may also cover at least a portion of a top of each of the plurality of leads and sides of the plurality of leads that are nearest the semiconductor die. At least a portion of the bottom of each of the plurality of leads and at least a portion of the sides of the plurality of leads that are farthest from the semiconductor die may be exposed outside the encapsulant.

In an embodiment, the method also includes applying the protective film to the lower surface of the semiconductor die before placing the semiconductor die in the die receiving area.

In another embodiment, the method also includes applying the protective film to the adhesive tape before placing the semiconductor die in the die receiving area.

In yet another embodiment, the frame includes the protective film extending over the adhesive tape in the die receiving area.

Numerous benefits are achieved using embodiments of the present invention over conventional techniques. For example, in some embodiments a protective layer may be used in a semiconductor package to replace a die attach paddle. The protective layer may be thinner than the die attach paddle it replaces and thus enable a reduction in thickness of the semiconductor package. Eliminating the die attach paddle also allows a number of leads (or input/output terminals) in a semiconductor package to be increased. This can improve electrical performance.

In other embodiments, the protective layer may cover a lower surface of a semiconductor die and be exposed along a lower surface of a semiconductor package. The protective layer can protect the semiconductor die during assembly and test processes. Depending on the embodiment, one or more of these benefits may exist. These and other benefits are described more fully below.

### BRIEF DESCRIPTION OF THE DRAWINGS

FIG. 1 is a simplified diagram of a conventional semiconductor package having a semiconductor die attached to a die attach paddle;

FIG. 2 is a simplified diagram of a conventional frame with a plurality of leads surrounding a die attach paddle;

FIG. 3 is a simplified diagram of a semiconductor package having a protective layer covering a lower surface of a semiconductor die in accordance with an embodiment of the invention;

FIG. 4 is a simplified diagram of a frame having a plurality of leads surrounding a die receiving area in accordance with an embodiment of the invention;

FIGS. 5-6 are simplified diagrams of semiconductor packages having protective layers covering lower surfaces of semiconductor die in accordance with other embodiments of the invention;

FIG. 7 is a simplified diagram of a leadframe strip having a plurality of inner frames each having leads surrounding a die receiving area in accordance with an embodiment of the invention; and

FIGS. 8-9 are flowcharts illustrating methods of forming semiconductor packages in accordance with embodiments of the invention.

### DETAILED DESCRIPTION

Embodiments of the present invention enable thickness and size of semiconductor packages to be reduced. The thickness and size can be reduced by using a protective layer in place of a die attach paddle. The thickness is reduced by reducing a thickness of the protective layer compared to a thickness of a die attach paddle it replaces. The size is reduced by reducing a size of an area between leads of a frame. The area can be reduced because eliminating the die attach paddle eliminates design rule constraints associated with minimum semiconductor die to die attach paddle size ratios.

It should be appreciated that the semiconductor packages shown in the figures and described below are used merely as examples and that the methods and structures described herein may be applied to a number of different types of semiconductor packages. These include quad-flat no-leads (QFN) packages, dual-flat no-leads (DFN) packages, micro leadframe packages (MLPs), and the like. Also, the various features shown in the figures are not intended to be drawn so scale.

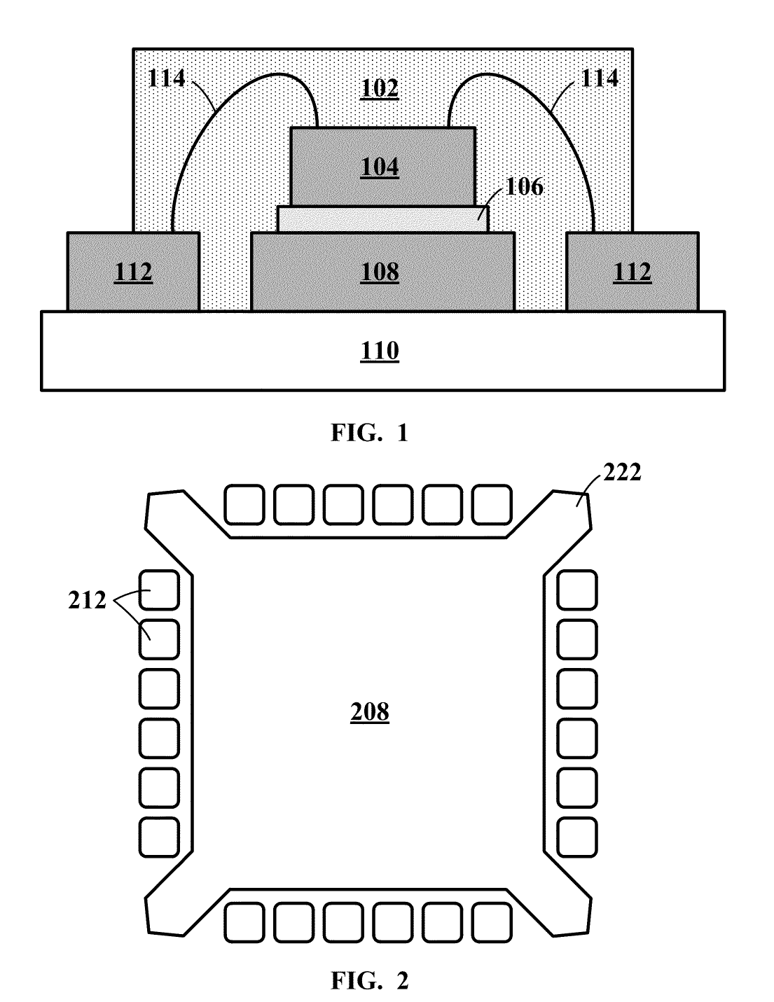

FIG. 1 is a simplified diagram of a conventional semiconductor package having a semiconductor die 104 attached to a die attach paddle 108. The semiconductor die 104 and the die attach paddle 108 are attached using an adhesive 106. Leads 112 are coupled to bond pads on an upper surface of the semiconductor die 104 using bonding wires 114. An encapsulant 102 covers the semiconductor die 104, the bonding wires 114, and the leads 112. The semiconductor package in this example is supported by a carrier 110. The carrier 110 may be an adhesive tape or a ring that is used to support the semiconductor package during an assembly process.

FIG. 2 is a simplified diagram of a conventional frame with a plurality of leads 212 surrounding a die attach paddle 208. The die attach paddle 208 is attached to the frame using tie bars 222. A semiconductor die is attached to the die attach paddle 208 and coupled to the leads 212 during an assembly process.

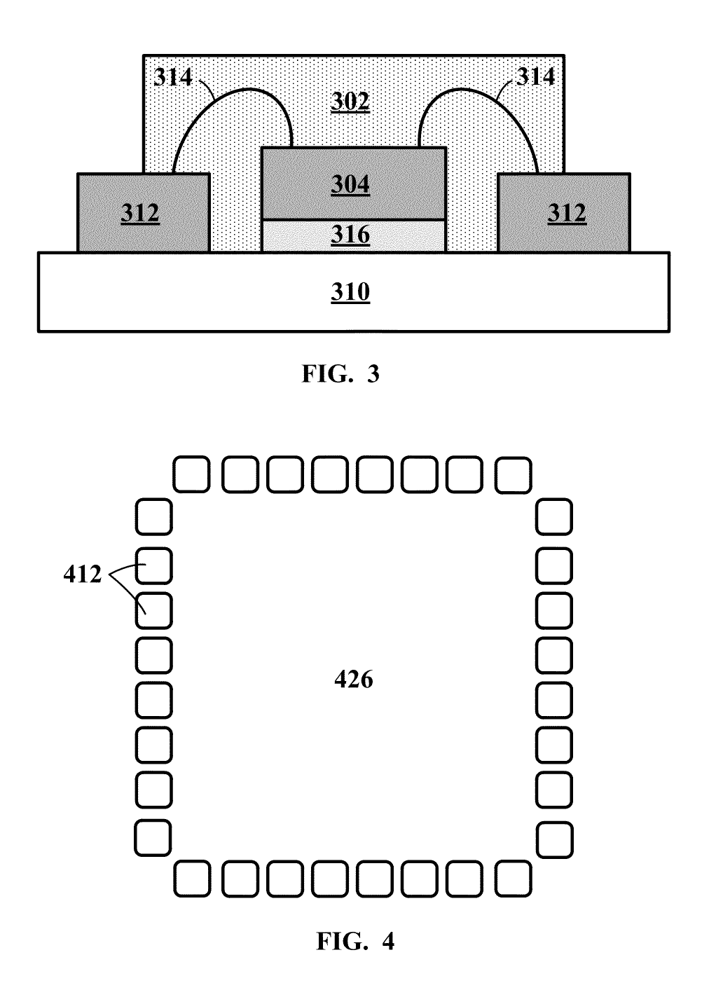

FIG. 3 is a simplified diagram of a semiconductor package having a protective layer 316 covering a lower surface of a semiconductor die 304 in accordance with an embodiment of the invention. The protective layer 316 may include one or more epoxy and/or adhesive die attach films (DAFs) and may be conductive or nonconductive depending on the particular application. In an embodiment, for example, the protective layer 316 includes a conventional thermally conductive adhesive. The protective layer 316 may be used in lieu of the die attach paddle 108 shown in FIG. 1. A thickness of the protective layer 316 may be less than a thickness of the die attach paddle 108 or less than a thickness of the die attach paddle 108 and the adhesive 106 shown in FIG. 1. A thickness of the protective layer 316 is typically greater than about 10 μm, however, to protect the semiconductor die 304 from damage. Without the protective layer 316 or without a protective layer 316 of sufficient thickness, the lower surface of the semiconductor die 304 is susceptible to mechanical and/or chemical damage during assembly, test, and surface mount processes.

Leads 312 surround sides of the semiconductor die 304 and are spaced from the sides of the semiconductor die 304. Bonding wires 314 couple bond pads on an upper surface of the semiconductor die 304 to the leads 312. An encapsulant 302 covers the upper surface and the sides of the semiconductor die 304 and the bonding wires 314. The encapsulant 302 also covers at least a portion of a top of the leads 312 and sides of the leads 312 that are nearest to the semiconductor die 304. A bottom of the leads 312 and the sides of the leads 312 that are farthest from the semiconductor die 304 are exposed outside the encapsulant 302. The sides of the leads 312 that are farthest from the semiconductor die 304 may extend beyond the encapsulant 302 as shown in this embodiment.

In this example the semiconductor package is supported by a carrier 310. The carrier 310 may be an adhesive tape or a ring that is used to support the semiconductor package during assembly processes. The semiconductor package may be removed from the carrier as part of the assembly process.

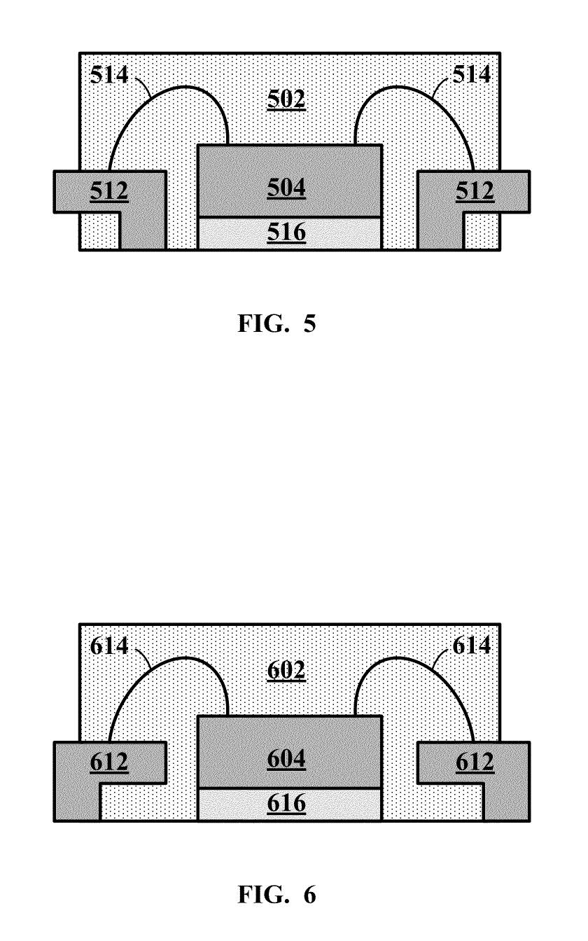

FIG. 4 is a simplified diagram of a frame having a plurality of leads 412 surrounding a die receiving area 426 in accordance with an embodiment of the invention. During assembly the frame may be one of many inner frames forming a leadframe strip. As explained more fully below, a semiconductor die may be placed in the die receiving area 426 during assembly. After singulation the frame and leads 412 may be separated from the leadframe strip and integrated (at least in part) into the semiconductor package.

Because the die attached paddle 208 and corresponding tie bars 222 shown in FIG. 2 are eliminated from the frame shown in FIG. 4, more leads 412 can be arranged surrounding the die receiving area 426. Increasing the number of leads 412 can increase the available input/output terminals of the semiconductor package and improve electrical performance.

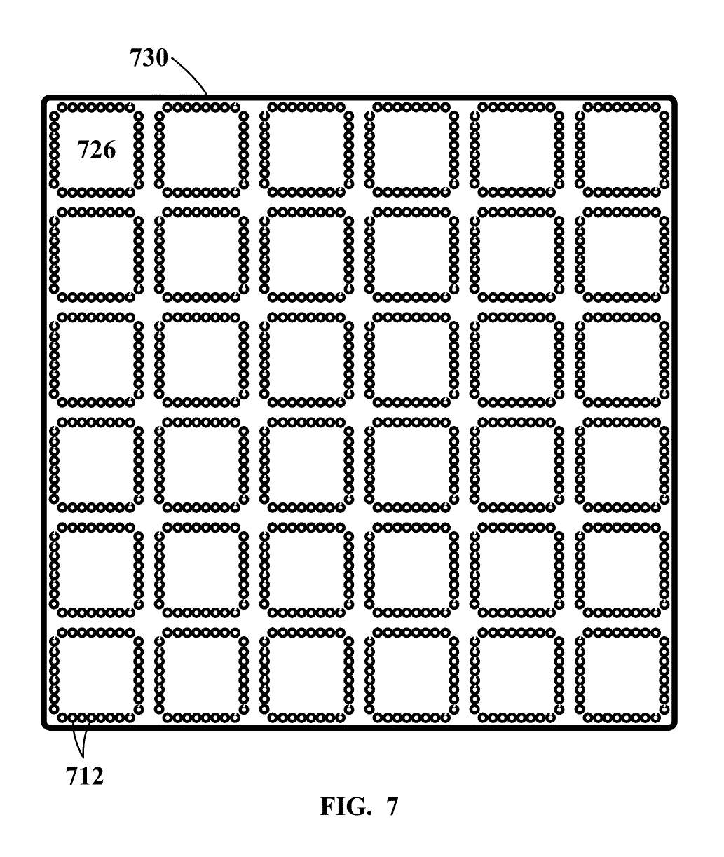

FIGS. 5-6 are simplified diagrams of semiconductor packages having protective layers covering lower surfaces of semiconductor die in accordance with other embodiments of the invention. The leads in these embodiments include notches along a bottom that are filled with encapsulant to secure the leads to the semiconductor package. In the embodiment shown in FIG. 5, an encapsulant 502 covers semiconductor die 504, bonding wires 514, and portions of leads 512. A protective layer 516 covers a lower surface of the semiconductor die 504. In this embodiment, the encapsulant 502 also extends under a portion of a bottom of each lead 512. A portion of the sides of the leads 512 that are farthest from the semiconductor die 504 are exposed outside the encapsulant 502.

In the embodiment shown in FIG. 6, an encapsulant 602 covers semiconductor die 604, bonding wires 614, and portions of leads 612. A protective layer 616 covers a lower surface of the semiconductor die 604. In this embodiment, the encapsulant 602 also extends under a portion of a bottom of each lead 612 and the sides of the leads 612 that are farthest from the semiconductor die 604 are exposed outside the encapsulant 602.

As can be seen in FIGS. 3 and 5-6, a bottom of the protective film 316, 516, 616 is exposed along a lower surface of the semiconductor package and is substantially coextensive with a bottom of the leads 312, 512, 612. Also, the bottom of the protective film 316, 516, 616 is substantially flush with the lower surface of the semiconductor package. Because the protective film 316, 516, 616 extends under the semiconductor die 304, 504, 604, a plane extending along the lower surface of the semiconductor die 304, 504, 604 lies above the bottom of the leads 312, 512, 612 and may be between a top and the bottom of the leads 312, 512, 612.

FIG. 7 is a simplified diagram of a leadframe strip 730 having a plurality of inner frames each having leads 712 surrounding a die receiving area 726 in accordance with an embodiment of the invention. It should be appreciated that the leadframe strip 730 may have a different number and/or arrangement of inner frames than that shown in this example. The inner frames may be attached to horizontal and vertical connecting bars (not shown) of the leadframe strip 730. An adhesive tape and/or a ring (i.e., carrier) may be attached to a backside of the leadframe strip 730 during assembly to support the leadframe strip 730 and to provide a means for handling the leadframe strip 730 by various assembly equipment. During singulation the inner frames may be separated from the leadframe strip 730 to provide individual semiconductor packages.

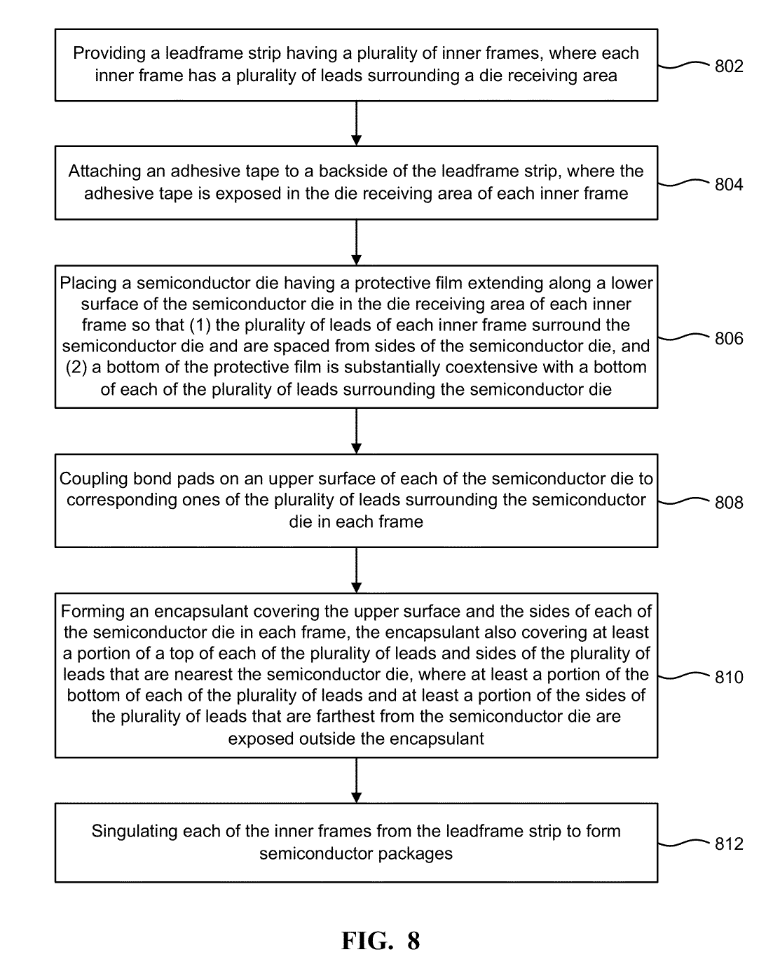

FIG. 8 is a flowchart illustrating a method of forming a semiconductor package in accordance with an embodiment of the invention. The method includes providing a leadframe strip having a plurality of inner frames, where each inner frame has a plurality of leads surrounding a die receiving area (802), and attaching an adhesive tape to a backside of the leadframe strip, where the adhesive tape is exposed in the die receiving area of each inner frame (804). The adhesive tape may be a high temperature tape capable of withstanding temperatures that may exceed 200° C. during some assembly processes (e.g., wirebonding and molding). In an alternative embodiment, a ring may be attached to the backside of the leadframe strip rather than using an adhesive tape.

The method also includes placing a semiconductor die having a protective film extending along a lower surface of the semiconductor die in the die receiving area of each inner frame so that (1) the plurality of leads of each inner frame surround the semiconductor die and are spaced from sides of the semiconductor die, and (2) a bottom of the protective film is substantially coextensive with a bottom of each of the plurality of leads surrounding the semiconductor die (806). The semiconductor die may be placed in the die receiving area using a conventional pick and place method. After each of the semiconductor die are placed in the die receiving area of each inner frame, a plane extending along the lower surface of each of the semiconductor die may lie between the top and the bottom of each of the plurality of leads surrounding the semiconductor die, the protective film along the lower surface of each of the semiconductor die may have a thickness of at least about 10 μm, and the bottom of the protective film may be substantially flush with a lower surface of the semiconductor package. In some embodiments, the protective film may comprises an epoxy and the method may include curing the epoxy. For example, in an embodiment the protective film may be cured using a conventional thermal treatment that includes exposure at a temperature of between about 100-200° C. for between about 1-3 hours.

The method also includes coupling bond pads on an upper surface of each of the semiconductor die to corresponding ones of the plurality of leads surrounding the semiconductor die in each frame (808). The bond pads may be coupled to the leads using a conventional wirebonding process.

The method also includes forming an encapsulant covering the upper surface and the sides of each of the semiconductor die in each frame, the encapsulant also covering at least a portion of a top of each of the plurality of leads and sides of the plurality of leads that are nearest the semiconductor die, where at least a portion of the bottom of each of the plurality of leads and at least a portion of the sides of the plurality of leads that are farthest from the semiconductor die are exposed outside the encapsulant (810). The encapsulant may be formed using a conventional molding process that includes dispensing an encapsulant material in an array mold cavity and submerging the leadframe, semiconductor die, and bonding wires in the encapsulant material. The molding process may include curing the encapsulant material.

The method also includes singulating each of the inner frames from the leadframe strip to form the semiconductor packages (812). This may involve a conventional saw or punch singulation process. After each of the inner frames are singulated from the leadframe strip, the bottom of the protective film may be exposed along a lower surface of each semiconductor package.

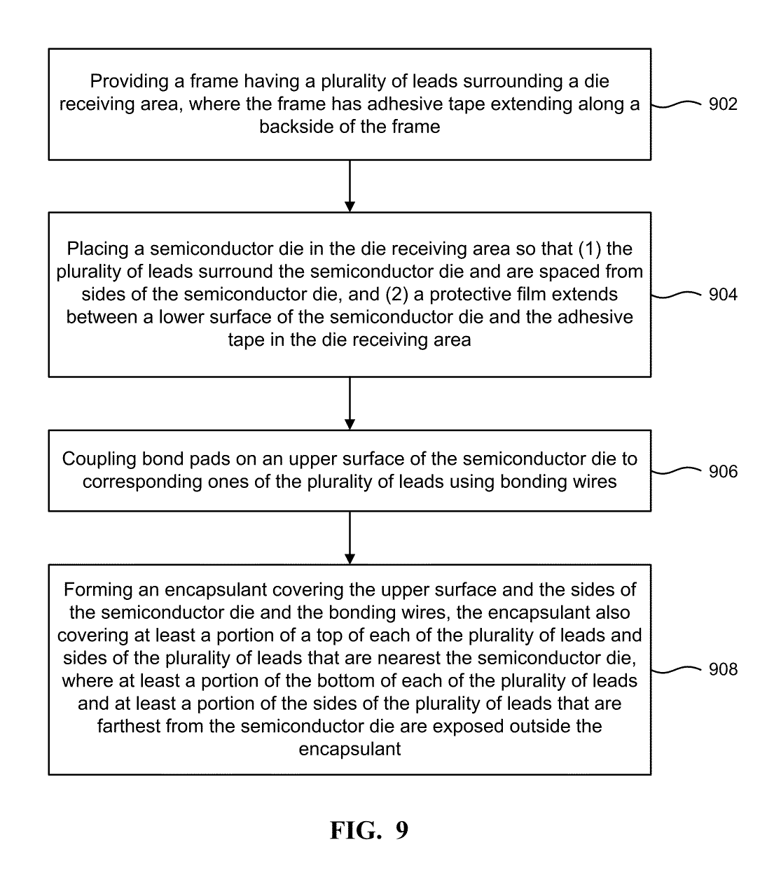

FIG. 9 is a flowchart illustrating a method of forming a semiconductor package in accordance with another embodiment of the invention. The method includes providing a frame having a plurality of leads surrounding a die receiving area, where the frame has an adhesive tape extending along a backside of the frame (902).

The method also includes placing a semiconductor die in the die receiving area so that (1) the plurality of leads surround the semiconductor die and are spaced from sides of the semiconductor die, and (2) a protective film extends between a lower surface of the semiconductor die and the adhesive tape in the die receiving area (904). In some embodiments, the protective film may be applied to the lower surface of the semiconductor die before placing the semiconductor die in the die receiving area. In other embodiments, the protective film may be applied to the adhesive tape before placing the semiconductor die in the die receiving area. In yet other embodiments, the frame may include the protective film extending over the adhesive tape in the die receiving area.

The method also includes coupling bond pads on an upper surface of the semiconductor die to corresponding ones of the plurality of leads using bonding wires (906).

The method also includes forming an encapsulant covering the upper surface and the sides of the semiconductor die and the bonding wires, the encapsulant also covering at least a portion of a top of each of the plurality of leads and sides of the plurality of leads that are nearest the semiconductor die, where at least a portion of the bottom of each of the plurality of leads and at least a portion of the sides of the plurality of leads that are farthest from the semiconductor die are exposed outside the encapsulant (908).

It should be appreciated that the specific steps illustrated in FIGS. 8-9 provide particular methods of forming semiconductor packages in accordance with embodiments of the present invention. The steps outlined above may be continuously repeated by system software. Other sequences of steps may also be performed according to alternative embodiments. For example, the steps outlined above may be performed in a different order. Moreover, the individual steps illustrated in FIGS. 8-9 may include multiple sub-steps that may be performed in various sequences as appropriate. Furthermore, additional steps may be added or removed depending on the particular application.

It should be noted that some embodiments of the present invention may be implemented by hardware, software, firmware, middleware, microcode, hardware description languages, or any combination thereof. When implemented in software, firmware, middleware, or microcode, the program code or code segments to perform the necessary tasks may be stored in a computer-readable medium such as a storage medium. Processors may be adapted to perform the necessary tasks. The term “computer-readable medium” includes, but is not limited to, portable or fixed storage devices, optical storage devices, sim cards, other smart cards, and various other mediums capable of storing, containing, or carrying instructions or data.

While the present invention has been described in terms of specific embodiments, it should be apparent to those skilled in the art that the scope of the present invention is not limited to the embodiments described herein. For example, features of one or more embodiments of the invention may be combined with one or more features of other embodiments without departing from the scope of the invention. The specification and drawings are, accordingly, to be regarded in an illustrative rather than a restrictive sense. Thus, the scope of the present invention should be determined not with reference to the above description but with reference to the appended claims along with their full scope of equivalents.

What is claimed is:

1. A semiconductor package comprising:
a semiconductor die having an upper surface, a lower surface, and sides, the upper surface of the semiconductor die having a plurality of bond pads thereon;
a plurality of leads surrounding the sides of the semiconductor die and spaced from the sides of the semiconductor die, each of the plurality of leads having a top, a bottom, and sides;
a plurality of bonding wires each coupling one of the plurality of bond pads on the upper surface of the semiconductor die to a corresponding one of the plurality of leads surrounding the semiconductor die;
an encapsulant covering the upper surface and the sides of the semiconductor die and the plurality of bonding wires, the encapsulant also covering at least a portion of the top of each of the plurality of leads and the sides of the plurality of leads that are nearest the semiconductor die, at least a portion of the bottom of each of the plurality of leads and at least a portion of the sides of the plurality of leads that are farthest from the semiconductor die being exposed outside the encapsulant; and
a protective film covering the lower surface of the semiconductor die, wherein a bottom of the protective film is substantially coextensive with at least a portion of the bottom of each of the plurality of leads.

2. The semiconductor package of claim 1 wherein a plane extending along the lower surface of the semiconductor die lies between the top and the bottom of each of the plurality of leads.

3. The semiconductor package of claim 1 wherein the bottom of the protective film is exposed along a lower surface of the semiconductor package.

4. The semiconductor package of claim 1 wherein the encapsulant extends under a portion of the bottom of each of the plurality of leads.

5. The semiconductor package of claim 1 wherein at least a portion of the bottom of each of the plurality of leads is exposed along a lower surface of the semiconductor package.

6. The semiconductor package of claim 1 wherein at least a portion of the sides of each of the plurality of leads that are farthest from the semiconductor die are exposed along a side of the semiconductor package.

7. The semiconductor package of claim 1 wherein the protective film comprises an epoxy.

8. The semiconductor package of claim 1 wherein the protective film has a thickness of at least about 10 μm.

9. The semiconductor package of claim 1 wherein the bottom of the protective film is exposed along a lower surface of the semiconductor package and is substantially flush with a lower surface of the semiconductor package.

10. A method of forming semiconductor packages, the method comprising:
providing a leadframe strip having a plurality of inner frames, each inner frame having a plurality of leads surrounding a die receiving area;
attaching an adhesive tape to a backside of the leadframe strip, the adhesive tape being exposed in the die receiving area of each inner frame;
placing a semiconductor die having a protective film extending along a lower surface of the semiconductor die in the die receiving area of each inner frame so that (1) the plurality of leads of each inner frame surround the semiconductor die and are spaced from sides of the semiconductor die, and (2) a bottom of the protective film is substantially coextensive with a bottom of each of the plurality of leads surrounding the semiconductor die;
coupling bond pads on an upper surface of each of the semiconductor die to corresponding ones of the plurality of leads surrounding the semiconductor die in each frame;
forming an encapsulant covering the upper surface and the sides of each of the semiconductor die in each frame, the encapsulant also covering at least a portion of a top of each of the plurality of leads and sides of the plurality of leads that are nearest the semiconductor die, at least a portion of the bottom of each of the plurality of leads and at least a portion of the sides of the plurality of leads that are farthest from the semiconductor die being exposed outside the encapsulant; and
singulating each of the inner frames from the leadframe strip to form the semiconductor packages.

11. The method of claim 10 wherein after each of the semiconductor die are placed in the die receiving area of each inner frame, a plane extending along the lower surface of each of the semiconductor die lies between the top and the bottom of each of the plurality of leads surrounding the semiconductor die.

12. The method of claim 10 wherein after each of the inner frames are singulated from the leadframe strip, the bottom of the protective film is exposed along a lower surface of each semiconductor package.

13. The method of claim 10 wherein the protective film comprises an epoxy.

14. The method of claim 10 wherein after each of the semiconductor die are placed in the die receiving area of each inner frame, the protective film along the lower surface of each of the semiconductor die has a thickness of at least about 10 μm.

15. The method of claim 10 wherein after each of the inner frames are singulated from the leadframe strip, the bottom of the protective film is substantially flush with a lower surface of the semiconductor package.

16. A method of forming a semiconductor package, the method comprising:
providing a frame having a plurality of leads surrounding a die receiving area, the frame having an adhesive tape extending along a backside of the frame;
placing a semiconductor die in the die receiving area so that (1) the plurality of leads surround the semiconductor die and are spaced from sides of the semiconductor die, and (2) a protective film extends between a lower surface of the semiconductor die and the adhesive tape in the die receiving area;
coupling bond pads on an upper surface of the semiconductor die to corresponding ones of the plurality of leads using bonding wires; and
forming an encapsulant covering the upper surface and the sides of the semiconductor die and the bonding wires, the encapsulant also covering at least a portion of a top of each of the plurality of leads and sides of the plurality of leads that are nearest the semiconductor die, at least a portion of the bottom of each of the plurality of leads and at least a portion of the sides of the plurality of leads that are farthest from the semiconductor die being exposed outside the encapsulant.

17. The method of claim 16 wherein a bottom of the protective film is substantially coextensive with the bottom of each of the plurality of leads.

18. The method of claim 16 further comprising applying the protective film to the lower surface of the semiconductor die before placing the semiconductor die in the die receiving area.

19. The method of claim 16 further comprising applying the protective film to the adhesive tape before placing the semiconductor die in the die receiving area.

20. The method of claim 16 wherein the frame includes the protective film extending over the adhesive tape in the die receiving area.
